(19) United States
(12) Patent Application Publication
(10) Pub. No.: US 2012/0241759 A1
(43) Pub. Date: Sep. 27, 2012

(54) NITRIDE SEMICONDUCTOR DEVICE AND ELECTRONIC DEVICE

(75) Inventors: Koji Matsunaga, Tokyo (JP); Masahiro Tanomura, Tokyo (JP)

(73) Assignee: NEC CORPORATION, Tokyo (JP)

(21) Appl. No.: 13/501,891

(22) PCT Filed: Oct. 15, 2010
(86) PCT No.: PCT/JP2010/068193

§ 371 Date: May 16, 2012

(30) Foreign Application Priority Data
Oct. 16, 2009 (JP) 2009-239179

(51) Int. Cl. H01L 29/20

(52) U.S. Cl. 257/76; 257/E29.089

(57) ABSTRACT

A nitride semiconductor device having a high withstand voltage and being capable of reducing a leakage current, is provided. The nitride semiconductor device 30 of the present invention includes: a nitride semiconductor stack; an anode 36; and cathodes 37 and 38. The nitride semiconductor stack includes: a channel layer 33 and a wide bandgap layer 35, stacked in this order. The anode 36 forms a Schottky junction with the wide bandgap layer 35. The cathodes 37 and 38 are joined to the channel layer 33. The channel layer 33 is an n⁺-type nitride semiconductor layer. The bandgap of the wide bandgap layer 35 is wider than that of the channel layer 33.

### TECHNICAL FIELD

The present invention relates to a nitride semiconductor device and an electronic device.

### BACKGROUND ART

As a semiconductor device which operates at high frequencies including the microwave band and the milliwave band, a nitride semiconductor device configuring a nitride-based diode is used, for example (e.g., see Patent Documents 1 and 2).

A nitride semiconductor device configuring a nitride-based diode disclosed in Patent Document 1 is shown in FIG. 7. As shown in FIG. 7, in this nitride semiconductor device 70, an n⁺-type GaN layer 73 (impurity concentration: 1×10¹⁸ cm⁻³ or more) and an n⁻-type GaN layer 74 (impurity concentration: 5×10¹⁴ to 5×10¹⁷ cm⁻³) are stacked on a substrate 71 in this order. An anode 76 such as usually Ti is formed on the n⁻-type GaN layer 74. Cathodes 77 and 78 are formed by ohmic contact on the surface of the n⁺-type GaN layer 73, exposed by etching the n⁻-type GaN layer 74.

A nitride semiconductor device configuring a nitride-based diode disclosed in Patent Document 2 is shown in FIG. 8. As shown in FIG. 8, in this nitride semiconductor device 80, an n⁺-type GaN layer 83 (layer to which an n⁺ impurity has been added), a n⁻-type GaN layer 84 (layer to which an n⁻ impurity has been added), and an undoped AlGaN layer (barrier layer) 85 are stacked on a substrate 81 in this order. An anode 86 is formed on the undoped AlGaN layer 85. Cathodes 87 and 88 are formed on the n⁺-type GaN layer 83. With this configuration, the barrier height is changed in this nitride semiconductor device.

When a positive voltage is applied to the anode side of such a nitride semiconductor device, a positive-side current flows at a voltage (Vf) across the Schottky bather. When the negative voltage is applied to the anode side, the n⁻-type GaN layer is depleted, which results in the pinch-off state. Thus, a big reverse withstand voltage can be obtained.

### PRIOR ART DOCUMENTS

### Patent Documents

Patent Document 1: JP 2006-191118 A
Patent Document 2: JP 2009-16875 A

### SUMMARY OF INVENTION

### Problem to be Solved by the Invention

However, in the Schottky characteristics on the n⁻-type GaN layer of the above-mentioned nitride semiconductor device disclosed in Patent Document 1, the barrier height with GaN is actually not sufficiently high. Therefore, the threshold value for the generation of the forward leakage current is low. Further, unlike in the Schottky characteristics of the GaAs-type diode, in the Schottky characteristics of the GaN-type diode, the Fermi level is not pinned. The barrier height is determined according to a work function with a metal. Therefore, it is difficult to control Vf. Because of the barrier height and the difficulty in controlling Vf, the reduction in leakage current is not sufficient. Thus, for example, the reduction in low frequency noise (flicker noise) is also not sufficient, for example.

In the nitride semiconductor device disclosed in Patent Document 2, carriers caused by the polarizing effect are generated at the interface between the undoped AlGaN layer and the n⁻-type GaN layer. By this generation of the carriers, the series resistance of a diode is reduced, and the high frequency characteristic is improved. However, when the thickness of the undoped AlGaN layer is increased, the polarization charge caused by piezoelectricity is increased. With this increase, a probability of carriers across the barrier layer, caused by the quantum tunnel effect, is also increased. Thus, the forward leakage current and reverse leakage current are increased.

Hence, the present invention is intended to provide a nitride semiconductor device having a high withstand voltage and being capable of reducing a leakage current, and electronic device.

### Means for Solving Problem

In order to achieve the aforementioned object, the present invention provides a nitride semiconductor device including: a nitride semiconductor stack including a channel layer and a wide bandgap layer, being stacked in this order; an anode; and a cathode, wherein the anode forms a Schottky junction with the wide bandgap layer, the cathode is joined to the channel layer, the channel layer is an n⁺-type nitride semiconductor layer, and a bandgap of the wide bandgap layer is wider than that of the channel layer.

The present invention also provides an electronic device including the nitride semiconductor device of the present invention.

### Effects of the Invention

According to the present invention, a nitride semiconductor device having a high withstand voltage and a reduced leakage current, and electronic device can be provided.

### BRIEF DESCRIPTION OF DRAWINGS

FIG. 1A is a cross-sectional view showing a configuration of an example (first embodiment) of the nitride semiconductor device of the present invention.

FIG. 1B is a cross-sectional view showing another example of a junction of a cathode in the nitride semiconductor device of the first embodiment.

FIG. 2 is a band diagram immediately below an anode in the nitride semiconductor device of the first embodiment.

FIG. 3 is a cross-sectional view showing a configuration of another example (second embodiment) of the nitride semiconductor device of the present invention.

FIG. 4 is a band diagram immediately below an anode in the nitride semiconductor device of the second embodiment.

FIG. 5 is a graph illustrating a low frequency noise characteristic in the present invention (first embodiment and second embodiment).

FIG. 6 is a cross-sectional view showing a configuration of yet another example (third embodiment) of the nitride semiconductor device of the present invention.

FIG. 7 is a cross-sectional view showing a configuration of an example of the nitride semiconductor device disclosed in Patent Document 1.

FIG. 8 is a cross-sectional view showing a configuration of an example of the nitride semiconductor device disclosed in Patent Document 2.

### DESCRIPTION OF EMBODIMENTS

The nitride semiconductor device of the present invention is described in detail below. The present invention, however, is by no means limited to the following embodiments. In the case where the present invention is specified by numerical limitations, it may be strictly specified by the numerical value or may be roughly specified by the numerical value.

### First Embodiment

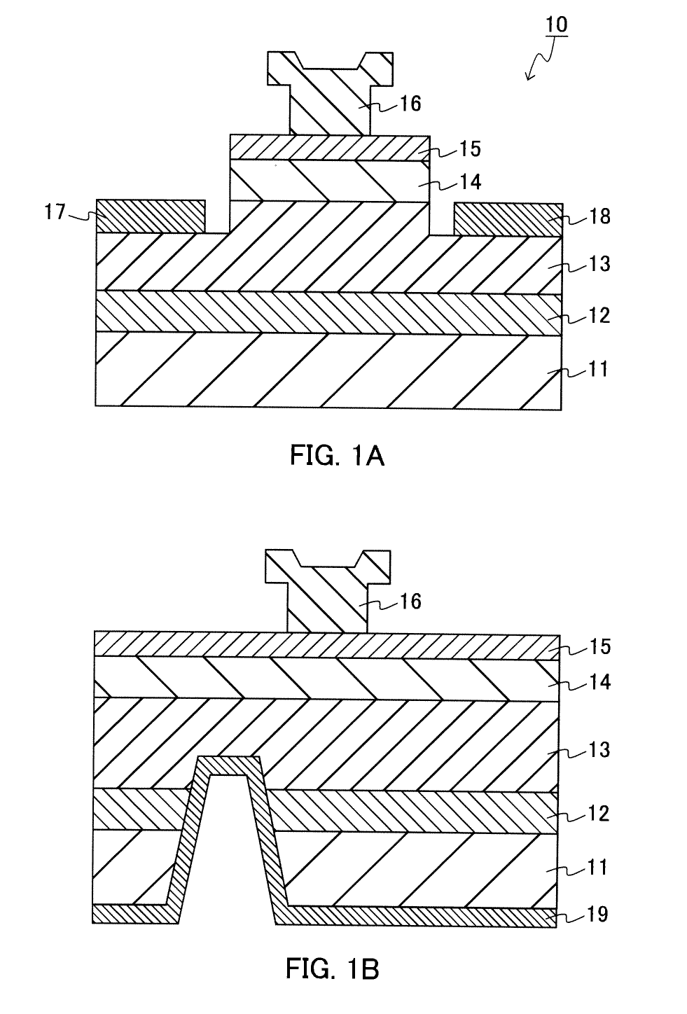

The configuration of the nitride semiconductor device of the present embodiment is shown in FIG. 1A. As shown in FIG. 1A, this nitride semiconductor device 10 includes: a nitride semiconductor stack; an anode 16; and cathodes 17 and 18. The nitride semiconductor device of the present embodiment further includes: a high-resistance substrate 11. The nitride semiconductor stack includes: an n⁺-type GaN layer (channel layer) 13; an undoped AlGaN layer (barrier layer) 14; and a SiN layer (wide bandgap layer) 15, stacked in this order. The n⁺-type GaN layer 13 is stacked on the high-resistance substrate 11 via a buffer layer 12. That is, the nitride semiconductor device of the present embodiment is a hetero junction type nitride semiconductor device. The anode 16 forms a Schottky junction with the SiN layer 15. The nitride semiconductor stack except the part below the anode 16 has a recess structure reaching from the SiN layer 15 to halfway along the thickness direction of the n⁺-type GaN layer 13. That is, by removing partially the SiN layer 15, the undoped AlGaN layer 14, and the upper part of the n⁺-type GaN layer 13, a notch part reaching from the upper surface of the SiN layer 15 to the upper part of the n⁺-type GaN layer 13 is formed. The cathodes 17 and 18 are joined to the bottom part of the recess structure (on the upper surface of the n⁺-type GaN layer 13). The bandgap of the SiN layer 15 is wider than that of the undoped AlGaN layer 14.

In the present invention, “joining” may be the state of being directly in contact or the state of connecting via another component. For example, the state where the cathode is joined to the n⁺-type GaN layer may be the state where the cathode is directly in contact with the n⁺-type GaN layer or the state where the cathode is connected to the n⁺-type GaN layer via the contact layer or the conductive substrate. In the present invention, the state of being “on the upper side” is not limited to a state of being directly in contact with the upper surface unless otherwise indicated and includes the state of being indirectly in contact with the upper surface, i.e., being above the upper surface via another component. Similarly, the state of being “on the lower side” may be the state of being directly in contact with the lower surface or the state of being indirectly in contact with the lower surface, i.e., being below the lower surface via another component, unless otherwise indicated. The state of being “on the upper surface” indicates the state of being directly in contact with the upper surface. Similarly, the state of being “on the lower surface” indicates the state of being directly in contact with the lower surface. The state of being “at the one side” may be the state of being directly in contact with the one side or the state of being indirectly in contact with the one side via another component, unless otherwise indicated. The same applies to the state of being “at the both sides”. The state of being “on the one side” indicates the state of being directly in contact with the one side. The same applies to a state of being “on the both sides”.

Examples of the high-resistance substrate include an insulating substrate and a semi-insulating substrate. Examples of a material for forming a high-resistance substrate include sapphire (Al₂O₃), silicon (Si), and silicon carbide (SiC). It is to be noted that the high-resistance substrate is used in the nitride semiconductor device of the present embodiment, and however, the present invention is by no means limited thereto.

In the nitride semiconductor device of the present embodiment, the n⁺-type GaN layer is stacked on the high-resistance substrate via the buffer layer as mentioned above. The present invention, however, is by no means limited thereto. The stacking may be stacking via no buffer layer. In this regard, however, the stacking via the buffer layer can relax the strain caused by a lattice mismatch between the high-resistance substrate and the n⁺-type GaN layer, for example.

The n⁺-type GaN layer is a GaN layer to which an n-type impurity has been added (doped) at high concentration. The concentration of the n-type impurity in the n⁺-type GaN layer is, for example, 5×10¹⁷ cm⁻³ or more. The upper limit of the concentration of the n-type impurity in the n⁺-type GaN layer is not particularly limited and is, for example, 5×10¹⁸ cm⁻³ or less. Examples of the n-type impurity include silicon (Si), sulfur (S), selenium (Se), and oxygen (O).

A material for forming the anode can be, for example, Au. A material for forming the cathode can be, for example, Al. Methods for forming the anode and the cathode are described below.

The nitride semiconductor device of the present embodiment can be produced as follows, for example.

First, a buffer layer, an n⁺-type GaN layer, an undoped AlGaN layer, and a SiN layer are stacked on a high-resistance substrate in this order using, for example, organometallic vapor phase epitaxy method (MOVPE method). Thus, a nitride semiconductor stack is formed. As the temperature condition, the pressure condition, and the like in formation of each layer by the MOVPE method, conventionally known conditions can be employed, for example.

Then, a part on the SiN layer of the nitride semiconductor stack, in which an anode is formed, is protected with a process film such as a resist. In this state, the other part on the SiN layer is removed by dry etching or the like. At that time, the n⁺-type GaN layer is exposed through the AlGaN layer, and further, the dry etching can be performed to the point of being subjected to over etching when the n⁺-type GaN layer is exposed halfway along the thickness direction thereof. In this case, for example, the impurity concentration in the n⁺-type GaN layer is set to 5×10¹⁷ cm⁻³ or more, and the thickness of the n⁺-type GaN layer is set to about 5000 Å (500 nm). Thus, the influence on the series resistance of a diode can be small because of the high concentration, for example, even though the over-etch depth in the n⁺-type GaN layer by the dry etching varies. Therefore, it is possible to reduce a variation in characteristics of the produced nitride semiconductor devices even thought an etching stopper layer is not used, for example.

Then, cathodes are formed by depositing and alloying the material for forming the cathode. Thereafter, in the state where the cathodes are protected with the respective process films, the anode is formed by depositing the material for forming the anode. Thus, the nitride semiconductor device of the present embodiment can be produced. The method for producing the nitride semiconductor device of the present embodiment, however, is by no means limited thereto.

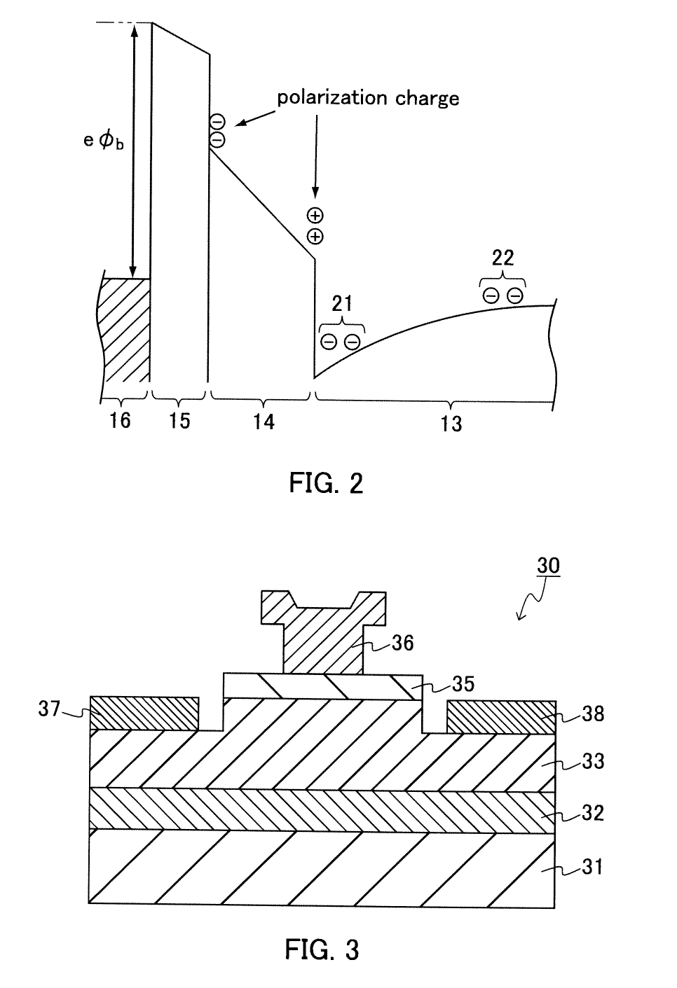

An example of the band diagram immediately below the anode 16 in the nitride semiconductor device of the present embodiment is shown in FIG. 2. As shown in FIG. 2, in the nitride semiconductor device of the present embodiment, an anode 16 forms a Schottky junction with a SiN layer 15 having the bandgap wider than that of an undoped AlGaN layer 14 as mentioned above. Therefore, the Schottky barrier height (ₑΦ_{b}) is sufficiently high. Thus, it is possible to reduce a leakage current in the nitride semiconductor device of the present embodiment.

As mentioned above, in the nitride semiconductor device of the present embodiment, an undoped AlGaN layer is used as a barrier layer. Therefore, as shown in FIG. 2, carriers (free electrons) generated by the polarization charge are stored at the interface between the undoped AlGaN layer 14 and the n⁺-type GaN layer 13 as two dimensional electron gas 21. Furthermore, carriers (free electrons) 22 are generated by the n⁺-type GaN layer 13 itself. Therefore, the carrier concentration is significantly increased in the whole nitride semiconductor device of the present embodiment, and for example, the drive capability as a diode is improved. In the nitride semiconductor device of the present embodiment, an undoped AlGaN layer is used as a barrier layer. The present invention, however, is by no means limited thereto, and it is only necessary that the bandgap of the barrier layer is wider than that of the n⁺-type GaN layer, for example.

Moreover, an n⁺-type GaN layer that is an n⁺-type nitride semiconductor layer is used as a channel layer (electron transport layer) in the nitride semiconductor device of the present embodiment, so that the nitride semiconductor device has a high withstand voltage. Therefore, the nitride semiconductor device of the present embodiment can achieve both of the low leakage current characteristic and the high withstand voltage characteristic. Furthermore, as mentioned above, the barrier height in the nitride semiconductor device of the present embodiment is sufficiently high. Therefore, the Fermi level is not pinned, and it is possible to reduce a leakage current even through GaN in which it is difficult to control Vf (forward voltage) is used, for example.

By appropriately controlling the thickness of the barrier layer, the excess increase in polarizing charge caused by piezoelectricity can be suppressed, for example. Therefore, the excess increase in probability that the carriers across the barrier layer by the quantum tunnel effect can be suppressed. Thus, for example, it is possible to achieve both of improving the drive capability as a diode by the increase in carriers caused by the above-mentioned polarizing charge and reducing the forward leakage current and the reverse leakage current in the nitride semiconductor device of the present embodiment.

In the present invention, the nitride semiconductor is not limited to GaN, and for example, any of the various group-III to V nitride semiconductors can be used. The group-III to V nitride semiconductors may be, for example, mixed crystals including group-V elements except nitrogen such as GaAsN, and preferably group-III nitride semiconductors including no group-V elements except nitrogen. Examples of the group-III nitride semiconductor include InGaN, AlGaN, InAlN, and InAlGaN in addition to GaN. The group-III to V nitride semiconductors more preferably are group-III to V nitride semiconductors each grown on the Ga face.

In the nitride semiconductor device of the present embodiment, a SiN layer is used as a wide bandgap layer. The present invention, however, is by no means limited thereto. It is only necessary that the bandgap of the wide bandgap layer is wider than that of the barrier layer. Examples of the wide bandgap layer include an AlN layer in addition to the SiN layer. The wide bandgap layer may be a single layer using only a single layer of the above-mentioned layers or a stack including two or more layers of the above-mentioned layers, stacked on each other.

In the nitride semiconductor device of the present embodiment, the recess structure is formed halfway along the thickness direction of the n⁺-type GaN layer. The present invention, however, is by no means limited thereto. The recess structure may be formed to the upper end surface of the n⁺-type GaN layer, for example. That is, in the present invention, the recess structure reaches from the upper surface of the layer stacked on the channel layer to the upper part of the channel layer, and “to the upper part of the channel layer” may be to the upper end surface of the channel layer. In FIG. 1A, the recess structure is a notch part, and however, it may be an opening part to be filled (an opening part in which at least a cathode is filled). The recess structure can be formed by removing partially the layer stacked on the cannel layer, for example. The channel layer may or may not be partially removed. As will be described below, the structure of the nitride semiconductor device of the present invention is not limited to the structure provided with the recess structure. The recess structure can be formed by conventionally known dry etching or the like, for example.

As mentioned above, in FIG. 1A, the cathodes are joined to the bottom part of the recess structure (the upper surface of the n⁺-type GaN layer 13). However, for example, the cathode may be joined to the n⁺-type GaN layer from the substrate side utilizing a via hole as shown in FIG. 1B. The structure of the nitride semiconductor device shown in FIG. 1B is described in detail below. That is, first, in the nitride semiconductor device shown in FIG. 1B, a high-resistance substrate 11 and a buffer layer 12 are partially removed, so that a via hole (a opening part to be filled) is formed. A cathode 19 is formed so as to be in contact with the lower surface of the high-resistance substrate 11, fill the via hole (opening part to be filled), and be directly in contact with the n⁺-type GaN layer 13. Thus, the cathode 19 is joined to the n⁺-type GaN layer 13. Except the above-mentioned point and the point of forming no recess structure, the configuration of this nitride semiconductor device is the same as that of the nitride semiconductor device 10 shown in FIG. 1A. In the case where a substrate is used in the nitride semiconductor device of the present invention, the substrate is not limited to the high-resistance substrate. The substrate may be, for example, a conductive substrate such as a GaN substrate. In the case of using the conductive substrate, the cathode 19 may be joined to the n⁺-type GaN layer 13 via the substrate 11 and the buffer layer 12 without forming a via hole in the structure of FIG. 1B, for example.

### Second Embodiment

The configuration of the nitride semiconductor device of the present embodiment is shown in FIG. 3. As shown in FIG. 3, this nitride semiconductor device 30 includes: a nitride semiconductor stack; an anode 36; and cathodes 37 and 38. The nitride semiconductor stack includes: an n⁺-type GaN layer 33; and a SiN layer 35, being stacked in this order. The n⁺-type GaN layer 33 is stacked on the high-resistance substrate 31 via a buffer layer 32. The anode 36 forms a Schottky junction with the SiN layer 35. The nitride semiconductor stack except the part below the anode 36 has a recess structure reaching from the SiN layer 35 to halfway along the thickness direction of the n⁺-type GaN layer 33. That is, by removing partially the layer (SiN layer 35) stacked on the n⁺-type GaN layer 33 (channel layer) and the upper part of the n⁺-type GaN layer 33 in the nitride semiconductor stack, a notch part reaching from the upper surface of the SiN layer 35 to the upper part of the n⁺-type GaN layer 33 can be formed. The cathodes 37 and 38 are joined to the bottom part of the recess structure (the upper surface of the n⁺-type GaN layer 33). The bandgap of the SiN layer 35 is wider than that of the n⁺-type GaN layer 33. The configuration of the nitride semiconductor device except the above-mentioned part is the same as that of the nitride semiconductor device 10. The components of the nitride semiconductor device of the present embodiment are, for example, the same as those of the first embodiment.

The nitride semiconductor device of the present embodiment can be produced as follows, for example.

First, a buffer layer, an n⁺-type GaN layer, and a SiN layer are stacked on a high-resistance substrate in this order using, for example, organometallic vapor phase epitaxy method (MOVPE method). Thus, a nitride semiconductor stack is formed. As the temperature condition, the pressure condition, and the like in formation of each layer by the MOVPE method, the conventionally known conditions can be employed, for example.

Then, a part on the SiN layer of the nitride semiconductor stack, in which an anode is formed, is protected with a process film such as a resist. In this state, the other part on the SiN layer is removed by dry etching or the like. At that time, the dry etching is performed halfway along the thickness direction of the n⁺-type GaN layer. In this case, for example, the impurity concentration in the n⁺-type GaN layer is set to 5×10¹⁷ cm⁻³ or more, and the thickness of the n⁺-type GaN layer is set to about 5000 Å (500 nm). Thus, the influence on the series resistance of a diode can be small because of the high concentration, for example, even though the over-etch depth in the n⁺-type GaN layer by the dry etching varies. Therefore, it is possible to reduce a variation in characteristics of the produced nitride semiconductor devices even thought an etching stopper layer is not used, for example.

Then, cathodes are formed by depositing and alloying the material for forming the cathode. Thereafter, in the state where the cathodes are protected with the respective process films, the anode is formed by depositing the material for forming the anode. Thus, the nitride semiconductor device of the present embodiment can be produced. The method for producing the nitride semiconductor device of the present embodiment, however, is by no means limited thereto.

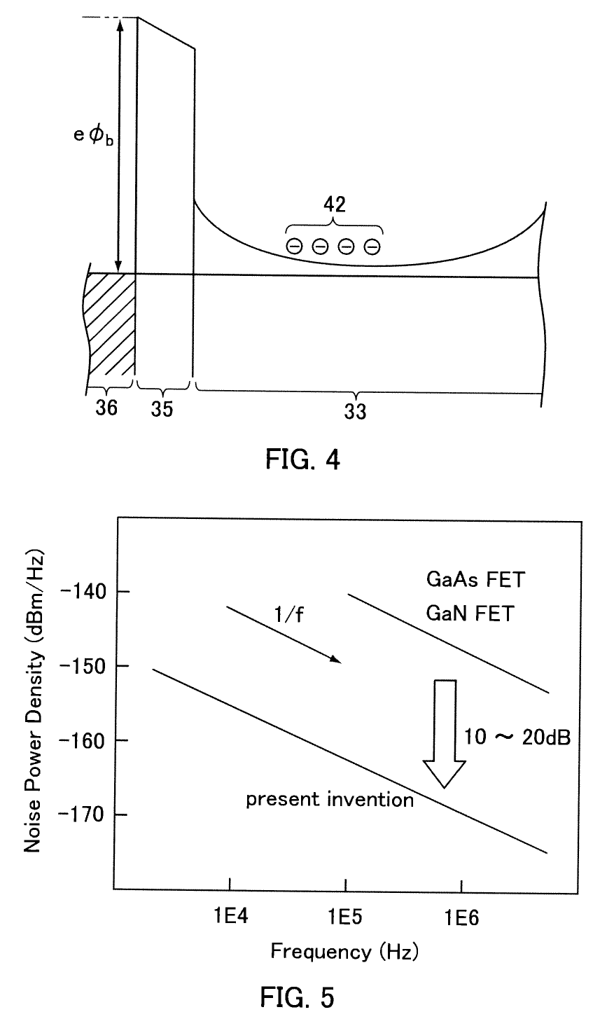

An example of the band diagram immediately below the anode 36 in the nitride semiconductor device of the present embodiment is shown in FIG. 4. As shown in FIG. 4, in the nitride semiconductor device of the present embodiment, an anode 36 forms a Schottky junction with a SiN layer 35 having the bandgap wider than that of an n⁺-type GaN layer 33 as mentioned above. Therefore, the Schottky barrier height (ₑΦ_{b}) is sufficiently high. Thus, it is possible to reduce a leakage current in the nitride semiconductor device of the present embodiment.

Moreover, carriers (free electrons) 42 are generated in the n⁺-type GaN layer 33 of the nitride semiconductor device of the present embodiment. Therefore, the carrier concentration is significantly increased in the whole nitride semiconductor device of the present embodiment, and, for example, the drive capability as a diode is improved.

The nitride semiconductor device of the present invention can reduce a leakage current as mentioned above. Moreover, in the nitride semiconductor device of the present invention, the electron transfer from an anode to a cathode becomes a vertical transfer. Therefore, the influence of the surface of the nitride semiconductor device is extremely small. Thus, as shown in FIG. 5, the nitride semiconductor device of the present invention can significantly reduce the low frequency noise characteristic (flicker noise) as a diode characteristic in the low frequency band as compared with the field effect transistor (FET) based semiconductor device, for example.

### Third Embodiment

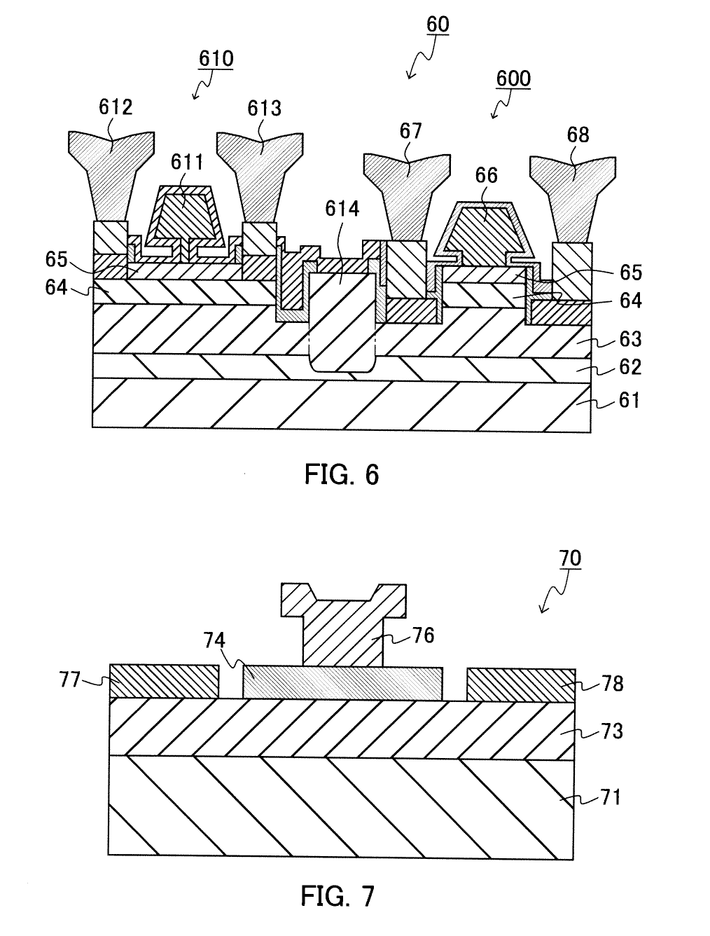

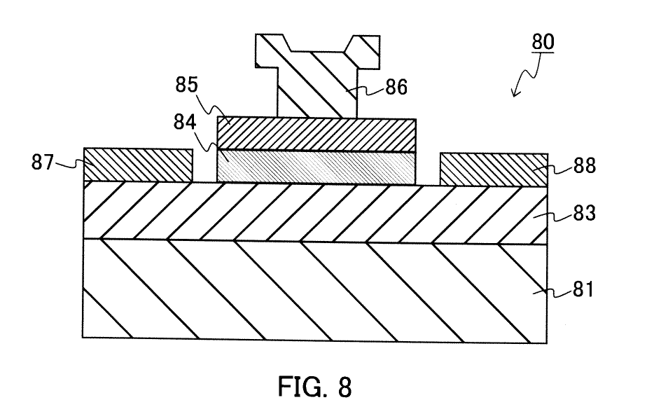

The configuration of the nitride semiconductor device of the present embodiment is shown in FIG. 6. As shown in FIG. 6, in this nitride semiconductor device 60, a diode part 600 and a field effect transistor (FET) part 610 are mounted on the same substrate in the state of being isolated by an isolation region 614. The configuration of the diode part 600 is the same as that of the nitride semiconductor device of the first embodiment. That is, the diode part 600 includes: a high-resistance substrate 61; a nitride semiconductor stack including an n⁺-type GaN layer 63, an undoped AlGaN layer 64, and a SiN layer 65, being stacked on the high-resistance substrate 61 in this order; an anode 66; and cathodes 67 and 68. The n⁺-type GaN layer 63 is stacked on the high-resistance substrate 61 via a buffer layer 62. The anode 66 forms a Schottky junction with the SiN layer 65. The nitride semiconductor stack except the part below the anode 66 has a recess structure reaching from the SiN layer 65 to halfway along the thickness direction of the n⁺-type GaN layer 63. The cathodes 67 and 68 are joined to the bottom surface of the recess structure (on the n⁺-type GaN layer 63) via a contact layer. Components of the diode part are, for example, the same as those of the first embodiment. As the contact layer, any of conventionally known contact layers can be used, for example.

The FET part 610 includes: the same nitride semiconductor stack as in the diode part 600; a gate electrode 611; a source electrode 612; and a drain electrode 613. The gate electrode 611 is joined to the SiN layer 65. The nitride semiconductor stack except the part below the gate electrode 611 has a recess structure reaching from the SiN layer 65 to the upper end surface of the undoped AlGaN layer 64. The source electrode 612 and the drain electrode 613 are joined to the bottom part of the recess structure (on the undoped AlGaN layer 64) via a contact layer. The contact layer is, for example, the same as the contact layer in the above-mentioned diode part.

The nitride semiconductor device of the present embodiment can be produced as follows, for example.

First, a nitride semiconductor stack is formed in the same manner as in the first embodiment.

Then, the respective parts on a SiN layer in the nitride semiconductor stack, in which an anode and a gate electrode are formed are protected with process films such as resists. In this state, the other part on the SiN layer is removed by dry etching or the like, so that a mesa shape is formed. At that time, in the diode part, the dry etching is performed halfway along the thickness direction of an n⁺-type GaN layer, and in the FET part, the dry etching is performed to the upper end of an undoped AlGaN layer.

Thereafter, a cathode is formed on the n⁺-type GaN layer, and a source electrode and a drain electrode are formed on the undoped AlGaN layer. In this state, implantation for isolation is performed. Thus, the diode part and the FET part are isolated.

Then, the anode in the diode part and the gate electrode in the FET part are patterned and formed on the SiN layer. Finally, electrical wiring is made (not shown in FIG. 6). Thus, the nitride semiconductor device of the present embodiment can be produced. The method for producing the nitride semiconductor device of the present embodiment, however, is by no means limited thereto.

In the nitride semiconductor device of the present embodiment, the diode part having high carrier concentration and exerting favorable Schottky characteristics and the FET part are mounted on the same substrate. Therefore, for example, a radio mounting SW, a converter, an amplifier, and the like can be configured at a time, and the low frequency noise can be significantly reduced. Thus, a high-performance radio can be configured.

The configuration of the diode part in the nitride semiconductor device of the present embodiment is the same as that of the nitride semiconductor device of the first embodiment. The present invention, however, is by no means limited thereto. The configuration of the diode part may be, for example, the same as that of the nitride semiconductor device of the second embodiment. In this case, the source electrode and the drain electrode are joined to the n⁺-type GaN layer via a contact layer, for example.

As described above, according to the present invention, a nitride semiconductor device having a high withstand voltage and a reduced leakage current can be provided. The nitride semiconductor device of the present invention is not particularly limited and can be used as a hetero junction type diode (Schottky diode or the like) that operates at high frequencies including the microwave band and the milliwave band, has a high withstand voltage and a low level of a low frequency noise characteristic, and uses a group-III to V nitride semiconductor as an electron transport layer, for example. The nitride semiconductor device of the present invention can be used widely in electronic devices such as various household electric appliances and communication equipment, for example.

The invention of the present application is described above with reference to the embodiments. However, various changes that can be understood by those skilled in the art can be made in the configurations and details of the invention within the scope of the invention of the present application.

This application claims priority from Japanese Patent Application No. 2009-239179 filed on Oct. 16, 2009. The entire subject matter of the Japanese Patent Application is incorporated herein by reference.

### EXPLANATION OF REFERENCE NUMERALS

10, 30, 60 nitride semiconductor device
11, 31, 61 high-resistance substrate
12, 32, 62 buffer layer
13, 33, 63 n⁺-type GaN layer (channel layer)
14, 64 undoped AlGaN layer (barrier layer)
15, 35, 65 SiN layer (wide bandgap layer)
16, 36, 66 anode
17, 18, 19, 37, 38, 67, 68 cathode
21 two dimensional electron gas
22, 42 carriers in n⁺-type GaN layer
70 nitride semiconductor device disclosed in Patent Document 1
71, 81 substrate
73, 83 n⁺-type GaN layer
74, 84 n⁻-type GaN layer
76, 86 anode
77, 78, 87, 88 cathode
80 nitride semiconductor device disclosed in Patent Document 2
85 undoped AlGaN layer
600 diode part
610 field effect transistor part
611 gate electrode
612 source electrode
613 drain electrode
614 isolation region

1. A nitride semiconductor device comprising:
a nitride semiconductor stack including a channel layer and a wide bandgap layer being stacked in this order;
an anode; and
a cathode, wherein
the anode forms a Schottky junction with the wide bandgap layer,
the cathode is joined to the channel layer,
the channel layer is an n⁺-type nitride semiconductor layer, and
a bandgap of the wide bandgap layer is wider than that of the channel layer.

2. The nitride semiconductor device according to claim 1, wherein
the nitride semiconductor stack further includes a barrier layer,
the channel layer and the wide bandgap layer are stacked on each other via the barrier layer, and
the bandgap of the wide bandgap layer is wider than that of the barrier layer.

3. The nitride semiconductor device according to claim 1, wherein
the n⁺-type nitride semiconductor layer is an n⁺-type GaN layer, and
the wide bandgap layer includes at least one of a SiN layer and an AlN layer.

4. The nitride semiconductor device according to claim 2, wherein
the n⁺-type nitride semiconductor layer is an n⁺-type GaN layer,
the barrier layer is an undoped AlGaN layer, and
the wide bandgap layer includes at least one of a SiN layer and an AlN layer.

5. The nitride semiconductor device according to claim 1, wherein
an opening part to be filled or a notch part, reaching from the upper surface of the layer stacked on the channel layer to the upper part of the channel layer, is formed in a part of the layer stacked on the channel layer of the nitride semiconductor stack, and
the cathode is joined to the upper surface of the channel layer.

6. The nitride semiconductor device according to claim 5, wherein
the opening part to be filled or the notch part is formed by removing the part of the layer stacked on the channel layer.

7. The nitride semiconductor device according to claim 1, wherein
an impurity concentration in the n⁺-type nitride semiconductor layer is 5×10¹⁷ cm⁻³ or more.

8. The nitride semiconductor device according to claim 1, further comprising:
a high-resistance substrate; and
a buffer layer, wherein
the channel layer is stacked on the high-resistance substrate via the buffer layer.

9. The nitride semiconductor device according to claim 1, being a Schottky diode.

10. A nitride semiconductor device comprising:
a substrate;
a diode part; and
a field effect transistor, wherein
the diode part and the field effect transistor are mounted on the substrate, and
the diode part is the nitride semiconductor device according to claim 9.

11. An electronic device comprising the nitride semiconductor device according to claim 1.
